(19) United States
(12) Patent Application Publication
(10) Pub. No.: US 2012/0008361 A1
(43) Pub. Date: Jan. 12, 2012

(54) SEMICONDUCTOR MEMORY DEVICE

(75) Inventor: Hee Youl LEE, Icheon-si (KR)

(73) Assignee: HYNIX SEMICONDUCTOR INC., Icheon-si (KR)

(21) Appl. No.: 13/176,775

(22) Filed: Jul. 6, 2011

(30) Foreign Application Priority Data
Jul. 7, 2010 (KR) 10-2010-0065353

(51) Int. Cl. G11C 5/06

(52) U.S. Cl. 365/63

(57) ABSTRACT

A semiconductor memory device includes cell gate lines arranged in parallel over a semiconductor substrate, gate lines for select transistors disposed over the semiconductor substrate adjacent to the gate lines of the outermost memory cells, from among the gate lines for the memory cells, and metal lines coupled to the select transistors through contacts.

### CROSS-REFERENCE TO RELATED APPLICATION

Priority is claimed to Korean patent application number 10-2010-0065353 filed on Jul. 7, 2010, the entire disclosure of which is incorporated by reference herein.

### BACKGROUND

Exemplary embodiments relate generally to a semiconductor memory device and, more particularly, to a semiconductor memory device capable of suppressing a shift of potential in a drain select line and a source select line due to coupling noise, occurring in word lines, bit lines, junctions, and wells, by increasing the volume of the drain select line and the source select line.

FIG. 1 is a circuit diagram showing the cell array of a known semiconductor memory device.

Referring to FIG. 1, the cell array of the semiconductor memory device includes a number of strings ST1 to STk coupled in parallel between a number of bit lines BL1 to BLk and a common source line CSL. Each of the strings ST1 to STk includes a drain select transistor DST, a number of memory cells MC<n;0>, and a source select transistor SST. The drain select transistors DST, the memory cells MC<n;0>, and the source select transistors SST of the strings share a drain select line DSL, a number of word lines WL<n;0>, and a source select line SSL.

The drain select transistor DST and the source select transistor SST are used to conduct electricity (precisely, turn on or off) between the memory cells MC<n;0> and external terminals (for example, a bit line BL1 and a common source line CSL). With higher degree of integration of devices, the influence of coupling noise increases due to the reduced between the common source line CSL, the word lines, source contacts, the bit line, drain contacts, and the well of a semiconductor substrate, disposed near the drain select transistor DST and the source select transistor SST.

FIG. 2 is a graph illustrating a shift of potential due to coupling noise resulting from the drain select line and the source select line.

With higher degree of integration of devices, capacitance increases due to reduced distance between the common source line CSL, the word lines, source contacts, the bit line, drain contacts, and the well of a semiconductor substrate, disposed near the drain select transistor DST and the source select transistor SST. The increased capacitance generates coupling noise. The coupling noise, when generated, increases the potentials of the drain select line DSL and the source select line SSL, thus deteriorating the OFF characteristics. Then in a program operation, this may reduce the channel boosting level of the cell array and generate a program disturbance phenomenon. Furthermore, in a read operation, this may increase the leakage current in the unselected blocks.

### BRIEF SUMMARY

Exemplary embodiments relate to a semiconductor memory device, having advantages of suppressing a shift of potential in a drain select line and a source select line due to coupling noise and quickly restoring a shift of potential due to coupling noise.

A semiconductor memory device according to an aspect of the present disclosure includes cell gate lines disposed over a semiconductor substrate a first select gate line disposed over the semiconductor substrate adjacent to an outermost one of the cell gate lines, and a first metal line coupled to the first select gate line through a plurality of contacts.

According to another aspect of this disclosure, there is provided a semiconductor memory device including first and second memory blocks sharing a common source line. Each of the first and the second memory blocks comprising cell gate lines disposed over a semiconductor substrate and a source select gate line disposed over the semiconductor substrate adjacent to an outermost one of the cell gate lines, first metal lines, wherein each of the first metal line is coupled to the source select gate line of the first memory block and the second memory block through a plurality of contacts.

The semiconductor memory device further includes second metal lines coupled to the first metal lines, respectively, and the first metal lines and the second metal lines are coupled through contacts.

### BRIEF DESCRIPTION OF THE DRAWINGS

FIG. 1 is a circuit diagram showing the cell array of a known semiconductor memory device;

FIG. 2 is a graph illustrating a shift of potential due to coupling noise resulting from a drain select line and a source select line;

FIG. 3 is a three-dimensional view showing a semiconductor memory device according to a first exemplary embodiment of this disclosure;

FIG. 4 is a cross-sectional view of a semiconductor memory device according to a second exemplary embodiment of this disclosure;

FIG. 5 is a three-dimensional view showing a semiconductor memory device according to a third exemplary embodiment of this disclosure;

FIG. 6 is a circuit diagram showing a semiconductor memory device according to a fourth exemplary embodiment of this disclosure; and

FIGS. 7A and 7B are graphs illustrating a shift of potential due to coupling noise resulting from a drain select line and a source select line in the known art and a shift of potential due to coupling noise resulting from a drain select line and a source select line according to the exemplary embodiments of this disclosure, respectively.

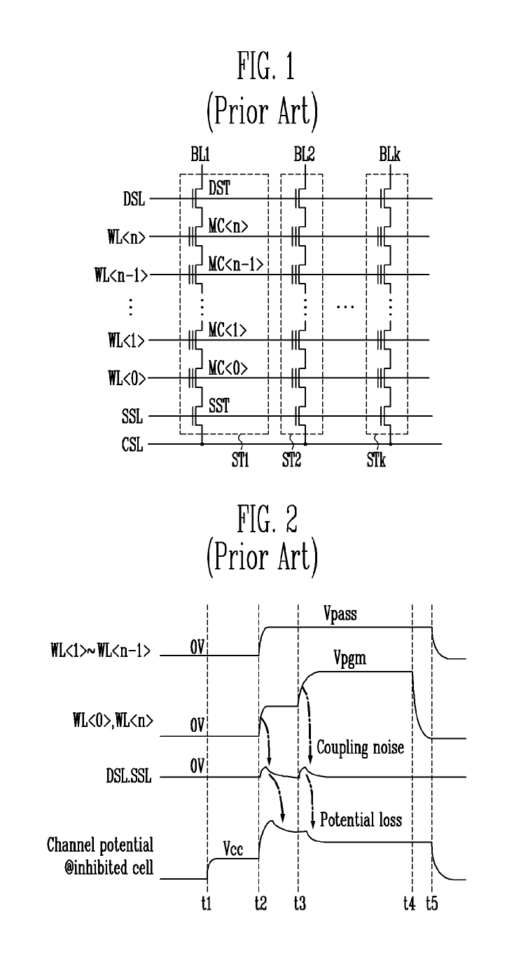

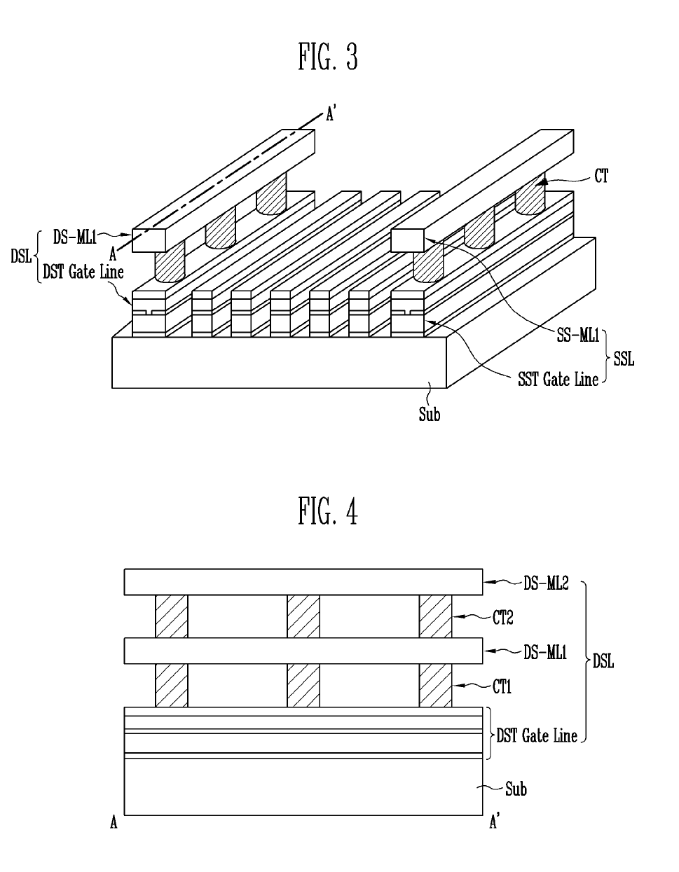

### DESCRIPTION OF EMBODIMENTS

Hereinafter, some exemplary embodiments of the present disclosure will be described in detail with reference to the accompanying drawings. The figures are provided to allow those having ordinary skill in the art to understand the scope of the embodiments of the disclosure.

FIG. 3 is a three-dimensional view showing a semiconductor memory device according to an exemplary embodiment of this disclosure.

Referring to FIG. 3, a plurality of cell gate lines is arranged over a semiconductor substrate Sub. A drain gate line DST Gate Line and a source gate line SST Gate Line are disposed over the semiconductor substrate Sub adjacent to the outermost cell gate lines.

The drain gate line DST Gate Line and the source gate line SST Gate Line are coupled to a metal line for a drain select line DS-ML1 the and a metal line for a source select line SS-ML1.

The drain gate line DST Gate Line and the metal line for the drain select line DS-ML1 are coupled through a plurality of contacts CT. With an increase in the number of contacts CT, the volume of the drain gate line DST Gate Line and the metal line DS-ML1 for the drain select line may increase. With increased number of contacts CT, the volume of the drain select line DSL, including the gate line DST Gate Line and the metal line DS-ML1 for the drain select line, may increase by the contacts CT, thereby increasing the capacitance due to neighboring common source lines, source contacts, bit lines, and drain contacts.

This reduces a shift of potential in the drain select line DSL. Furthermore, resistance is reduced because the number of contacts CT is increased.

The gate line SST Gate Line and the metal line SS-ML1 for the source select line are coupled through the plurality of contacts CT. Increasing number of contacts CT increases the volume of the source select line SSL, including the gate line SST Gate Line and the metal line for the source select line SS-ML1. The volume of the source select line SSL is increased by the increased volume of contacts CT. Accordingly, capacitance is increased owing to the neighboring common source lines, source contacts, bit lines, and drain contacts. A shift of potential in the source select line SSL is reduced. Furthermore, resistance is reduced because the number of contacts CT is increased.

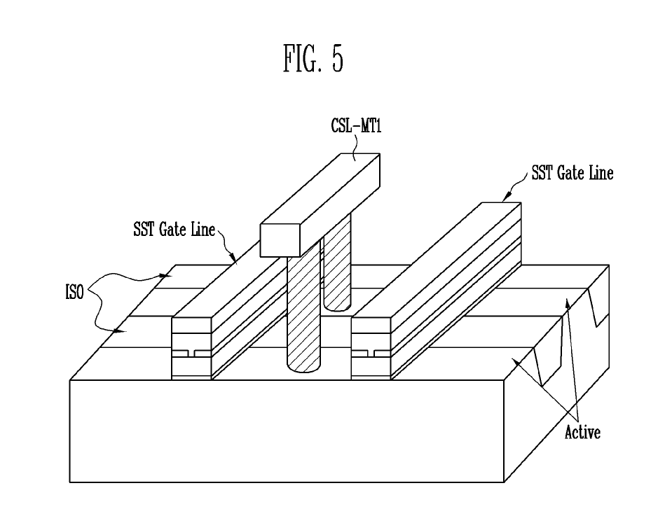

FIG. 4 is a cross-sectional view of a semiconductor memory device such as that shown in FIG. 3 along A-A′ but comprising more than one metal lines DS-ML therein according to an exemplary embodiment of this disclosure.

Referring to FIG. 4, a gate line DST Gate Line is disposed over a semiconductor substrate Sub. As in FIG. 3, the gate line DST Gate Line is coupled to a first metal line for a drain select line DS-ML1 through a plurality of first contacts CT1. Furthermore, the first metal line for the drain select line DS-ML1 is coupled to a second metal line for the drain select line DS-ML2 through a plurality of second contacts CT2. With increased number of the second contacts CT2 coupling the first metal line for the drain select line DS-ML1 and the second metal line for the drain select line DS-ML2, the volume of the drain select line DSL may increase by the volume of the contacts CT. Accordingly, the capacitance is increased owing to the neighboring common source lines, source contacts, bit lines, and drain contacts. A shift of potential in the drain select line DSL is reduced. Furthermore, resistance is reduced because the number of contacts CT is increased.

By coupling the first metal line for the source select line and the second metal line for the source select line through the plurality of contacts, a shift of potential can be reduced.

Furthermore, although the entire volume of the drain select line and the source select line is increased by coupling a third metal line (not shown), coupled to the second metal line for the drain select line DS-ML2, and a third metal line (not shown), coupled to the second metal line for the source select line, through a plurality of contacts, a shift of potential due to coupling noise can be reduced.

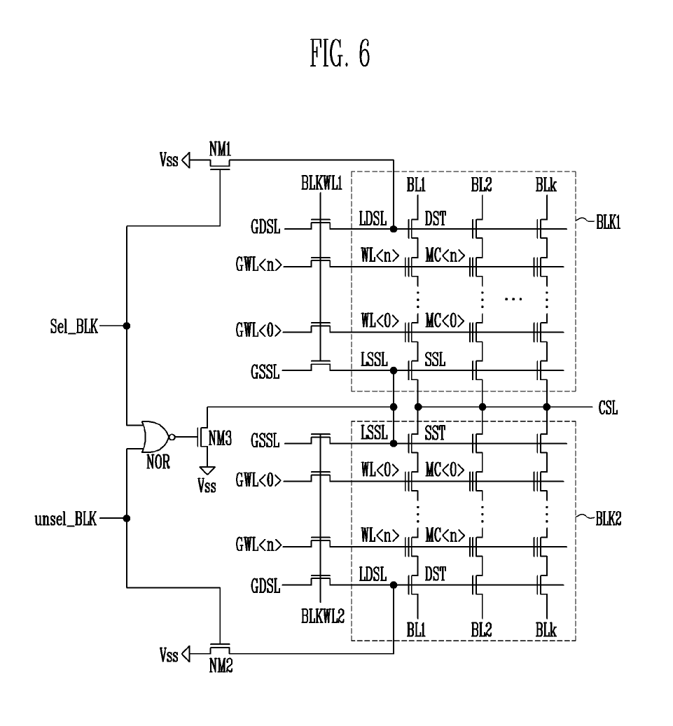

FIG. 5 is a three-dimensional view showing a semiconductor memory device according to an exemplary embodiment of this disclosure.

Referring to FIG. 5, two source gate lines are arranged in parallel over a semiconductor substrate, including active regions Active and isolation regions ISO. The active regions Active between the two source gate line s SST Gate Line are coupled to a metal line CSL-MT1 for a common source line through contacts. Here, each of the contacts has a cylindrical form. Because of the cylindrical form, the entire volume of the common source line is reduced as, for example, compared to a contact of non-cylindrical form such as a line form, and thus the coupling noise due to the common source line is reduced. Accordingly, a shift of potential in the source select line is reduced.

FIG. 6 is a circuit diagram showing a semiconductor memory device according to an embodiment of this disclosure.

Referring to FIG. 6, the local source select lines LSSL of first and second memory blocks BLK1 and BLK2, sharing a common source line CSL, are coupled. In performing program and read operations on a specific memory block (for example, the first memory block BLK1), the local source select line LSSL of the first memory block BLK1 is coupled to the local source select line LSSL of the second memory block BLK2, thereby increasing the entire volume of a source select line SSL, so as to reduce a shift of potential.

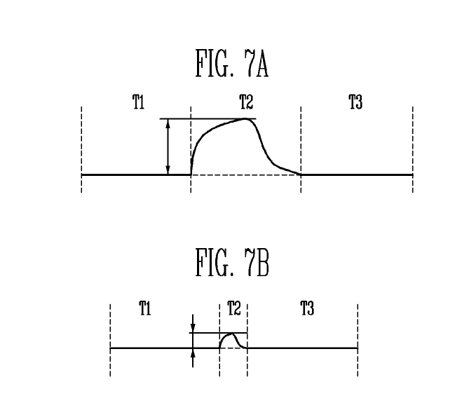

FIG. 7A illustrates a shift of potential due to coupling noise resulting from the drain select line and the source select line in the known art, and FIG. 7B illustrates a shift of potential due to coupling noise resulting from the drain select line and the source select line according to exemplary embodiments of this disclosure.

Referring to FIGS. 7A and 7B, it can be seen that a shift of potential due to the coupling noise in various embodiment of the disclosure described above is smaller than a shift of potential due to coupling noise in the known art, because the entire volume of the drain select line and the source select line is increased. It can also be seen that, although potential of the drain select line and the source select line is shifted owing to coupling noise, the shift of potential is restored faster as compared to the known art.

According to exemplary embodiments of this disclosure, the select gate lines and the metal lines of the semiconductor memory device are coupled through the contacts, thereby increasing the entire volume of the select lines. Accordingly, a shift of potential due to coupling noise resulting from neighboring word lines, junctions, and well can be suppressed and the resistance value of the select lines can be reduced. Consequently, although potential of the select line is shifted owing to coupling noise, the shifted potential can be restored faster.

What is claimed is:

1. A semiconductor memory device, comprising:
cell gate lines disposed over a semiconductor substrate a first select gate line disposed over the semiconductor substrate adjacent to an outermost one of the cell gate lines; and
a first metal line coupled to the first select gate line through a plurality of contacts.

2. The semiconductor memory device of claim 1, further comprising;
a second select gate line disposed over the semiconductor substrate adjacent to another outermost one of the cell gate lines.

3. The semiconductor memory device of claim 2, further comprising;
a second metal line coupled to the second select gate line through a plurality of contacts.

4. The semiconductor memory device of claim 1, further comprising;
a third metal line coupled to the first metal line through a plurality of upper contacts.

5. The semiconductor memory device of claim 3, further comprising;
a fourth metal line coupled to the second metal line through a plurality of upper contacts.

6. The semiconductor memory device of claim 2, wherein the first select gate line is a source select gate line and the second select gate line is a drain select gate line.

7. A semiconductor memory device comprising first and second memory blocks sharing a common source line, each of the first and the second memory blocks comprising:
cell gate lines disposed over a semiconductor substrate; and
a source select gate line disposed over the semiconductor substrate adjacent to an outermost one of the cell gate lines;
first metal lines, wherein each of the first metal line is coupled to the source select gate line of the first memory block and the second memory block through a plurality of contacts.

8. The semiconductor memory device of claim 7, each of the first and the second memory blocks further comprising;
a drain select gate line disposed over the semiconductor substrate adjacent to another outermost one of the cell gate lines.

9. The semiconductor memory device of claim 8, further comprising;
second metal lines, wherein each of the second metal line is coupled to the drain select gate line of the first memory block and the second memory block through a plurality of contacts

10. The semiconductor memory device of claim 7, wherein the common source line is disposed between the source select gate line of the first memory block and the source gate line of the second memory block.

11. The semiconductor memory device of claim 7, wherein the first metal line coupled to the source select gate line of the first memory block is coupled to the first metal line coupled to the source gate line the second memory block.

12. The semiconductor memory device of claim 7, further comprising;
third metal lines coupled to the first metal lines through a plurality of upper contacts, respectively.

13. The semiconductor memory device of claim 9, further comprising;
fourth metal lines coupled to the second metal lines through a plurality of upper contacts, respectively.

14. The semiconductor memory device of claim 7, the common source line comprises a metal line, coupled to active regions between the first memory block and the first memory block, through cylindrical contacts.
